(19) United States
(12) Patent Application Publication
(10) Pub. No.: US 2025/0151403 A1
(43) Pub. Date: May 8, 2025

(54) ARRAY SUBSTRATE

(71) Applicant: SHENZHEN CHINA STAR OPTOELECTRONICS SEMICONDUCTOR DISPLAY TECHNOLOGY CO., LTD., Shenzhen (CN)

(72) Inventors: Macai LU, Shenzhen (CN); Jiangbo YAO, Shenzhen (CN)

(21) Appl. No.: 19/004,270

(22) Filed: Dec. 28, 2024

Related U.S. Application Data
(63) Continuation of application No. 17/426,907, filed on Jul. 29, 2021, now Pat. No. 12,218,143.

(30) Foreign Application Priority Data
Mar. 29, 2021 (CN) 202110334360.5

(51) Int. Cl. H10D 86/60; H10D 86/01; H10D 86/40

(52) U.S. Cl. CPC H10D 86/60; H10D 86/0221; H10D 86/421; H10D 86/471; H10D 86/481

(57) ABSTRACT

An array substrate includes a substrate, an active layer, a first insulating layer, a first metal layer, a second insulating layer, a second metal layer and a barrier layer. The array substrate includes a thin film transistor (TFT) area, the first metal layer includes a gate sub-layer located in the TFT area, and an orthographic projection of the barrier layer covers at least part of an orthographic projection of an active layer exposed area in the TFT area on the active layer. The TFT area includes a driving TFT sub-area located in which the gate sub-layer includes a first gate, the active layer includes a first active sub-layer and the barrier layer includes a first barrier sub-layer, and an orthographic projection of the first barrier sub-layer on the first active sub-layer covers at least part of an orthographic projection of the first gate on the first active sub-layer.

### CROSS-REFERENCE TO RELATED APPLICATIONS

This application is a continuation of U.S. application Ser. No. 17/426,907, filed Jul. 29, 2021, which is a National Stage of International Application No. PCT/CN2021/095939, filed May 26, 2021, which claims the benefit of and priority to Chinese Application No. 202110334360.5, filed Mar. 29, 2021, the entireties of which are hereby incorporated herein by reference.

### TECHNICAL FIELD

This application relates to display technologies, and in particular to an array substrate.

### BACKGROUND

With development of display technology, in current-driven display devices such as organic light-emitting diode (OLED) displays, mini light-emitting diodes (mini-LEDs), and micro light-emitting diodes (micro-LEDs), thin film transistors (TFTs) with greater current passing capacity and better device stability are required.

Currently, top-gate self-aligned oxide semiconductor thin film transistors with higher carrier mobility, less parasitic capacitance, and low leakage current are generally used. However, because the thin film transistor with a top gate structure has no film barrier in an area between a gate and a source and a drain, an active layer is easily permeated by water and oxygen or directly irradiated by light, which affects the performance of thin film transistor (TFT) devices, and reduces weather resistance of the TFT devices.

### SUMMARY

According to some embodiments of the present application, an array substrate includes a substrate, an active layer disposed on the substrate, a first insulating layer disposed on the substrate and the active layer, a first metal layer disposed on the first insulating layer, a second insulating layer disposed on the substrate, the active layer, the first insulating layer, and the first metal layer and covering the first insulating layer and the first metal layer, and a second metal layer disposed on the second insulating layer. The array substrate has a thin film transistor (TFT) area, the first metal layer includes a gate sub-layer located in the TFT area, the second metal layer includes a source-drain metal sub-layer located in the TFT area, the TFT area includes an active layer exposed area located between the gate sub-layer and the source-drain metal sub-layer. The array substrate further includes a barrier layer located above the active layer, and an orthographic projection of the barrier layer on the active layer covers at least part of an orthographic projection of the active layer exposed area on the active layer. The TFT area includes a driving TFT sub-area, the gate sub-layer includes a first gate located in the driving TFT sub-area, the active layer includes a first active sub-layer located in the driving TFT sub-area, the barrier layer includes a first barrier sub-layer located in the driving TFT sub-area, and an orthographic projection of the first barrier sub-layer on the first active sub-layer covers at least part of an orthographic projection of the first gate on the first active sub-layer.

### BRIEF DESCRIPTION OF THE DRAWINGS

FIG. 1 is a schematic structural diagram of an array substrate according to some embodiments of the present application.

FIG. 2 is a schematic structural diagram of a pixel driving circuit according to some embodiments of the present application.

FIG. 3 is a schematic flowchart of a method for manufacturing an array substrate according to some embodiments of the present application.

FIG. 4 to FIG. 7 schematically shows the array substrate in respective processes of a method for manufacturing an array substrate according to some embodiments of the present application.

### DETAILED DESCRIPTION

Some embodiments of the present application will be described in detail below with reference to the accompanying drawings. The embodiments are described for illustrative purposes only and are not intended to limit the present application.

The description of the embodiments refers to the attached drawings to illustrate specific embodiments in which the present application can be implemented. The directional terms mentioned in the present application, such as “above”, “below”, “front”, “back”, “left”, “right”, “inside”, “outside”, “side”, etc., are only directions for referring to the attached drawings. Therefore, the directional terms are used to describe and understand the present application, rather than to limit the present application. In the figure, units with similar structures are indicated by the same reference numerals.

In the description of this application, the terms “first” and “second” are only used for descriptive purposes, and cannot be understood as indicating or implying relative importance or implicitly indicating the number of indicated technical features. Therefore, the features defined with “first” and “second” may explicitly or implicitly include one or more of the features. In the description of the present application, “plurality” means two or more than two, unless otherwise specifically defined.

In the description of the present application, it should be noted that the terms “installation”, “connected to”, or “connection” should be understood in a broad sense, unless otherwise specified and limited. For example, it can be a fixed connection, a detachable connection, or an integral connection. It can be mechanically connected, electrically connected, or can be communicated with each other. It can be directly connected or indirectly connected through an intermediary. It can be a communication between two elements or an interaction relationship between two elements. For one of ordinary skill in the art, the specific meanings of the above terms in the application can be understood according to specific circumstances.

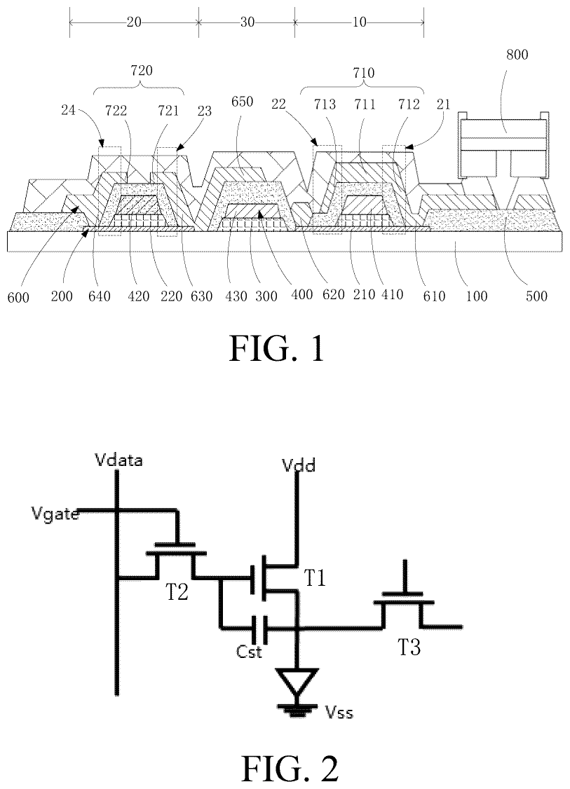

Some embodiments of the present application provide an array substrate, as shown in FIG. 1 and FIG. 7. The array substrate includes a substrate 100, an active layer 200 disposed on the substrate 100, a first insulating layer 300 disposed on the substrate 100 and the active layer 200, a first metal layer 400 disposed on the first insulating layer 300, a second insulating layer 500 disposed on the substrate 100, the active layer 200, the first insulating layer 300, and the first metal layer 400 and covering the first insulating layer 300 and the first metal layer 400, and a second metal layer 600 disposed on the second insulating layer 500.

The array substrate includes a TFT area. The first metal layer 400 includes a gate sub-layer located in the TFT area. The second metal layer 600 includes a source-drain metal sub-layer located in the TFT area, and the TFT area includes an active layer exposed area 2 located between the gate sub-layer and the source-drain metal sub-layer. The array substrate includes a barrier layer 700 located above the active layer 200, where an orthographic projection of the barrier layer 700 on the active layer 200 covers at least part of an orthographic projection of the active layer exposed area 2 on the active layer 200.

It is understandable that the present current-driven display devices such as organic light-emitting diode displays, mini light-emitting diodes, and micro light-emitting diodes require thin film transistors with larger current passing capacity and better device stability. Therefore, top-gate self-aligned oxide semiconductor thin film transistors with higher carrier mobility, less parasitic capacitance, and low leakage current are generally used. However, because thin film transistors with top gate structures have no film barrier in the area between the gate and the source and drain, an active layer is easily permeated by water and oxygen or directly irradiated by light, which affects the performance of TFT devices, and reduces weather resistance of the TFT devices. In this embodiment, a barrier layer 700 is provided at the active layer exposed area 2 between the gate sub-layer and the source-drain metal sub-layers, so that the orthographic projection of the barrier layer 700 on the active layer 200 covers at least part of the orthographic projection of the active layer exposed area 2 on the active layer 200. The barrier layer 700 not only plays a role in blocking water and oxygen, but also blocks direct irradiation of light to the active layer 200 at the active layer exposed area 2. This prevents the structure of the thin film transistor from being permeated by water and oxygen or directly irradiated by light to affect the performance of thin film transistor devices, thereby improving the weather resistance of the thin film transistor devices.

It should be noted that, as shown in FIG. 2, it is a structural schematic diagram of a pixel driving circuit for driving a light-emitting element. The pixel driving circuit includes at least a switch thin film transistor T2, a reset detection thin film transistor T3, a storage capacitor Cₛₜ, and a driving thin film transistor T1 for generating a driving current. In this embodiment, the thin film transistors are arranged in the TFT area. Specifically, the switch thin film transistor T2 and the driving thin film transistor T1 can be arranged in the TFT area. Furthermore, the first metal layer 400 may not only include the gate sub-layer, but also may include structures such as gate traces. In addition to the source-drain metal sub-layer, the second metal layer 600 may also include trace structures such as data lines and storage capacitor lines, which are not limited herein.

In one embodiment, the barrier layer 700 is disposed on the second insulating layer 500, and the barrier layer 700 and the second metal layer 600 are formed in the same process. It is understandable that the barrier layer 700 can be made of the same material as the second metal layer 600. Furthermore, the barrier layer 700 and the second metal layer 600 can be formed on the second insulating layer 500 by the same process. Specifically, the material of the barrier layer 700 and the second metal layer 600 can be a metal material or a metal oxide material.

In one embodiment, as shown in FIG. 1 and FIG. 7, the TFT area includes a driving TFT sub-area 10, and the gate sub-layer includes a first gate 410 located in the driving TFT sub-area 10. The source-drain metal sub-layer includes a first source 610 and a first drain 620 located in the driving TFT sub-area 10. The active layer exposed area 2 includes a first exposed sub-area 21 located between the first source 610 and the first gate 410 and a second exposed sub-area 22 located between the first drain 620 and the first gate 410. The barrier layer 700 includes a first barrier sub-layer 710, and the active layer 200 includes a first active sub-layer 210 located in the driving TFT sub-area 10.

The orthographic projection of the first barrier sub-layer 710 on the first active sub-layer 210 covers at least part of the orthographic projection of the first exposed sub-area 21 on the first active sub-layer 210, and/or the orthographic projection of the first barrier sub-layer 710 on the first active sub-layer 210 covers at least part of the orthographic projection of the second exposed sub-area 22 on the first active sub-layer 210.

It can be understood that the first source 610, the first drain 620, and the first barrier sub-layer 710 are arranged in the same layer. The first source 610, the first drain 620, and the first barrier sub-layer 710 can be formed by the same process and have an integrally formed structure. The driving thin film transistor T1 can be provided in the driving TFT sub-area 10. In this embodiment, the driving thin film transistor T1 may include the first gate 410, the first source 610, and the first drain 620. The first source 610 is connected to a mini light-emitting diode 800. The orthographic projection of the first barrier sub-layer 710 on the first active sub-layer 210 covers at least part of the orthographic projection of the first exposed sub-area 21 on the first active sub-layer 210, and/or the orthographic projection of the first barrier sub-layer 710 on the first active sub-layer 210 covers at least part of the orthographic projection of the second exposed sub-area 22 on the first active sub-layer 210 so that the first barrier sub-layer 710 covers at least part of the portion of the first active sub-layer 210 located in the first exposed sub-area 21 and/or the second exposed sub-area 22. It has the effect of blocking water and oxygen and preventing direct light to a certain extent.

In one embodiment, as shown in FIG. 1 to FIG. 2, the orthographic projection of the first barrier sub-layer 710 on the first active sub-layer 210 covers at least part of the orthographic projection of the first gate 410 on the first active sub-layer 210. It is understandable that when the orthographic projection of the first barrier sub-layer 710 on the first active sub-layer 210 covers at least part of the orthographic projection of the first gate 410 on the first active sub-layer 210, the first barrier sub-layer 710 can form a capacitor with the first gate 410. Specifically, as shown in FIG. 2, in the driving thin film transistor T1, when the first gate 410 receives a data voltage signal Vdata to turn on the first drain 620 and the first drain 620 to drive the display, the capacitance formed by the first barrier sub-layer 710 and the first gate 410 can improve the electrical characteristics such as voltage retention of the driving thin film transistor T1.

In one embodiment, as shown in FIG. 1, the first barrier sub-layer 710 includes a barrier body 711 disposed above the first gate 410, a first branch 712 extending from one end of the barrier body 711 to the first exposed sub-area 21, and a second branch 713 extending from another end of the barrier body 711 to the second exposed sub-area 22. An orthographic projection of the barrier body 711 on the first active sub-layer 210 covers an orthographic projection of the first gate 410 on the first active sub-layer 210. An end of the first branch 712 away from the barrier body 711 is connected to the first source 610, or an end of the second branch 713 away from the barrier body 711 is connected to the first drain 620.

It is understandable that the first barrier sub-layer 710 includes a barrier body 711 disposed above the first gate 410 and a first branch 712 and a second branch 713 respectively extending from both ends of the barrier body 711 to the first exposed sub-area 21 and the second exposed sub-area 22. In this case, the first barrier sub-layer 710 may completely cover the first gate 410. Compared with the first barrier sub-layer 710 partially covering the first gate 410, the capacitance formed by the first barrier sub-layer 710 and the first gate 410 is increased, and the voltage retention and other electrical characteristics of the driving thin film transistor T1 are maximized. In addition, by adopting a structure in which an end of the first branch 712 away from the barrier body 711 is connected to the first source 610 or an end of the second branch 713 away from the barrier body 711 is connected to the first drain 620, the first barrier sub-layer 710 can at least completely cover the orthographic projection of the first exposed sub-area 21 or the second exposed sub-area 22 on the first active sub-layer 210. Specifically, when the end of the first branch 712 away from the barrier body 711 is connected to the first source 610, the first branch 712 in the first barrier sub-layer 710 completely covers the orthographic projection of the first exposed sub-area 21 on the first active sub-layer 210, and when the end of the second branch 713 away from the barrier body 711 is connected to the first drain 620, the second branch 713 in the first barrier sub-layer 710 completely covers the orthographic projection of the second exposed sub-area 22 on the first active sub-layer 210. On the basis of maximizing the improvement of the voltage retention and other electrical characteristics of the driving thin film transistor T1, it also maximizes the shielding area of the first barrier sub-layer 710 to the first active sub-layer 210. This ensures that the first barrier sub-layer 710 has certain water and oxygen barrier and light-shielding effects on the first active sub-layer 210.

It should be noted that the first branch 712, the second branch 713, and the barrier body 711 can be configured in other forms. One of the first branch 712 or the second branch 713 is connected to the barrier body 711, and the other one is spaced apart from the barrier body 711. It may also be that the first branch 712, the second branch 713, and the barrier body 711 are arranged at intervals. In addition, based on the above structure, the orthographic projection of the barrier body 711 on the first active sub-layer 210 can be set to partially cover the orthographic projection of the first gate 410 on the first active sub-layer. In this situation, the orthographic projection of the first branch 712 on the first active sub-layer 210 can be set to completely cover the orthographic projection of the first exposed sub-area 21 on the first active sub-layer 210. In addition, the orthographic projection of the second branch 713 on the first active sub-layer 210 is set to completely cover the orthographic projection of the second exposed sub-area 22 on the first active sub-layer 210, which is not limited herein.

In one embodiment, as shown in FIG. 1, the TFT area includes a switch TFT sub-area 20. The gate sub-layer includes a second gate 420 located in the switch TFT sub-area 20. The source-drain metal sub-layer includes a second source 630 and a second drain 640 located in the switch TFT sub-area 20. The active layer exposed area 2 includes a third exposed sub-area 23 located between the second source 630 and the second gate 420 and a fourth exposed sub-area 24 located between the second drain 640 and the second gate 420. The barrier layer 700 includes a second barrier sub-layer 720, and the active layer 200 includes a second active sub-layer 220 located in the switch TFT sub-area 20. The orthographic projection of the second barrier sub-layer 720 on the second active sub-layer 220 covers at least part of the orthographic projection of the third exposed sub-area 23 on the second active sub-layer 220, and/or the orthographic projection of the second barrier sub-layer 720 on the second active sub-layer 220 covers at least part of the orthographic projection of the fourth exposed sub-area 24 on the second active sub-layer 220.

It can be understood that the second source 630, the second drain 640, and the second barrier sub-layer 720 are arranged in the same layer. The second source 630, the second drain 640, and the second barrier sub-layer 720 can be formed by the same process and have an integrally formed structure. A data switch thin film transistor T2 can be arranged in the switch TFT sub-area 20. In this embodiment, the data switch thin film transistor T2 may include the second gate 420, the second source 630, and the second drain 640. The orthographic projection of the second barrier sub-layer 720 on the second active sub-layer 220 covers at least part of the orthographic projection of the third exposed sub-area 23 on the second active sub-layer 220, and/or the orthographic projection of the second barrier sub-layer 720 on the second active sub-layer 220 covers at least part of the orthographic projection of the fourth exposed sub-area 24 on the second active sub-layer 220 so that the second barrier sub-layer 720 covers at least part of a part of the second active sub-layer 220 located in the third exposed sub-area 23 and/or the fourth exposed sub-area 24. It has the effect of blocking water and oxygen and preventing direct light to a certain extent.

In one embodiment, as shown in FIG. 1, the second barrier sub-layer 720 includes first sub-segments 721 or second sub-segments 722 arranged at intervals. An orthographic projection of the first sub-segment 721 on the second active sub-layer 220 covers an orthographic projection of the third exposed sub-area 23 on the second active sub-layer 220, and an orthographic projection of the second sub-segment 722 on the second active sub-layer 220 covers an orthographic projection of the fourth exposed sub-area 24 on the second active sub-layer 220.

It can be understood that the orthographic projection of the first sub-segment 721 on the second active sub-layer 220 is set to completely cover the orthographic projection of the third exposed sub-area 23 on the second active sub-layer 220, and the orthographic projection of the second sub-segment 722 on the second active sub-layer 220 is set to completely cover the orthographic projection of the fourth exposed sub-area 24 on the second active sub-layer 220. In this way, the second barrier sub-layer 720 can completely cover the part of the second active sub-layer 220 located in the third exposed sub-area 23 and the fourth exposed sub-area 24. This exerts good water and oxygen barrier properties and prevents light from directly irradiating the third exposed sub-area 23 and fourth exposed sub-area 24.

In one embodiment, as shown in FIG. 1, the first sub-segment 721 is connected to the second source 630, and the second sub-segment 722 is connected to the second drain 640. An end of the first sub-segment 721 away from the second source 630 extends above the second gate 420, and/or an end of the second sub-segment 722 away from the second drain 640 extends above the second gate 420.

It is understandable that a data switch thin film transistor T2 can be provided in the switch TFT sub-area 20. In this embodiment, the data switch thin film transistor T2 includes the second gate 420, the second source 630, and the second drain 640. Specifically, the data switch thin film transistor T2 needs to function as a data switch in the pixel circuit, that is, to charge and discharge. In this embodiment, an end of the first sub-segment 721 away from the second source 630 extends above the second gate 420, and/or an end of the second sub-segment 722 away from the second drain 640 extends above the second gate 420. That is, the orthographic projection of the first sub-segment 721 and/or the second sub-segment 722 on the second active sub-layer 220 partially covers the orthographic projection of the second gate 420 on the second active sub-layer 220. In addition, the first sub-segment 721 and the second sub-segment 722 are arranged at intervals, so as to ensure that the second barrier sub-layer 720 does not completely cover the second gate 420 and to prevent the formation of a capacitance between the second barrier sub-layer 720 and the second gate 420 which causes a decrease in the charge and discharge sensitivity of the data switch thin film transistor T2. This ensures the charge and discharge sensitivity of the data switch thin film transistor T2. Specifically, the distance between the first sub-segment 721 and the second sub-segment 722 is greater than 2 um.

It should be noted that an end of the first sub-segment 721 away from the second source 630 extends above the second gate 420, and/or an end of the second sub-segment 722 away from the second drain 640 extends above the second gate 420. It is possible to increase the water and oxygen barrier capacity and the area that blocks direct light rays of the first sub-segment 721 and/or the second sub-segment 722. On the basis of maximizing the prevention of the formation of capacitance with the second gate 420 to reduce the charge and discharge sensitivity of the data switch thin film transistor T2, the water and oxygen blocking capacity and the function of blocking light irradiation of the first sub-segment 721 and the second sub-segment 722 are maximized.

In one embodiment, as shown in FIG. 1, the array substrate further includes a storage capacitor area 30. The first metal layer 400 includes a first electrode plate 430 located in the storage capacitor area 30. The second metal layer 600 includes a second electrode plate 650 located in the storage capacitor area 30. An end of the second electrode plate 650 is connected to the second source 630 or the second drain 640. In this embodiment, an end of the second electrode plate 650 is connected to the second source 630.

The orthographic projection of the second electrode plate 650 on the substrate 100 covers at least part of the orthographic projection of the first electrode plate 430 on the substrate 100.

It can be understood that, as shown in FIG. 1 to FIG. 2, the storage capacitor area 30 can be used to set a storage capacitor Cₛₜ. In this embodiment, the first metal layer 400 includes a first electrode plate 430 located in the storage capacitor area 30, and the second metal layer 600 includes a second electrode plate 650 located in the storage capacitor area 30. The orthographic projection of the second electrode plate 650 on the substrate 100 covers at least part of the orthographic projection of the first electrode plate 430 on the substrate 100. The storage capacitor Cₛₜ may include the first electrode plate 430 and the second electrode plate 650. Certainly, the orthographic projection of the second electrode plate 650 on the substrate 100 can completely cover the orthographic projection of the first electrode plate 430 on the substrate 100, thereby increasing the facing area of the first electrode plate 430 and the second electrode plate 650. Specifically, the size of the facing area of the first electrode plate 430 and the second electrode plate 650 can be adjusted according to the requirements for the size of the storage capacitor Cₛₜ. In addition, the second electrode plate 650 can also be connected to the second source 630 or the second drain 640, and the second electrode plate 650, the second source 630, and the second drain 640 can be manufactured by the same process and are integrally formed.

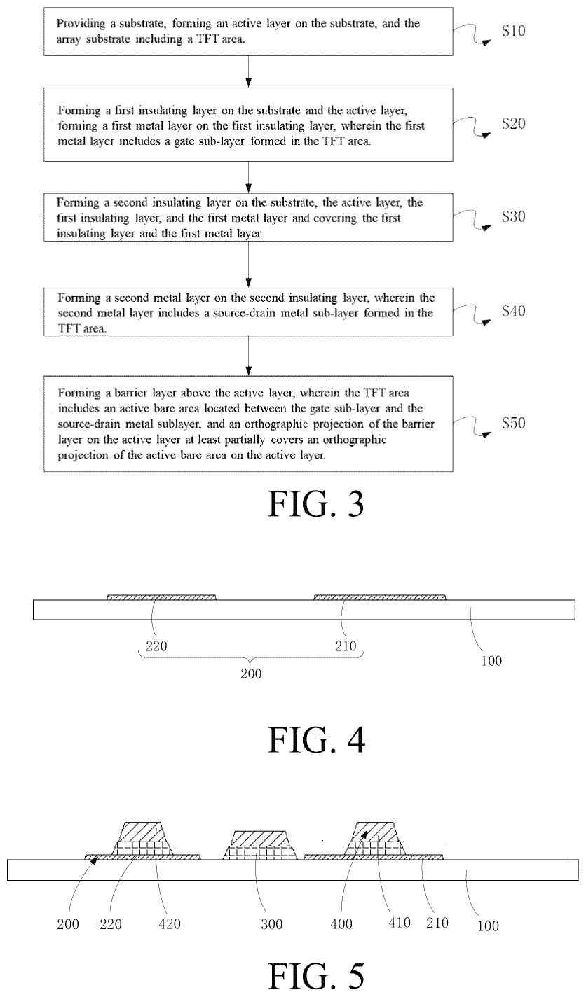

Some embodiments of the present application further provide a method of manufacturing an array substrate, as shown in FIG. 3, including following steps:

S10: As shown in FIG. 4, providing a substrate 100 and forming an active layer 200 on the substrate 100 including a TFT area. Specifically, the active layer 200 can be formed by coating and patterning on the substrate 100. The material of the active layer 200 may be an oxide semiconductor material such as indium gallium zinc oxide (IGZO).

S20: As shown in FIG. 5, forming a first insulating layer 300 on the substrate 100 and the active layer 200, and forming a first metal layer 400 on the first insulating layer 300 where the first metal layer 400 includes a gate sub-layer formed in the TFT area. Specifically, the first insulating layer 300 is a gate insulating layer. The first metal layer 400 includes a first gate 410 and a second gate 420 located in the TFT area. The first insulating layer 300 may be formed by patterning using the first gate 410 and the second gate 420 as a mask.

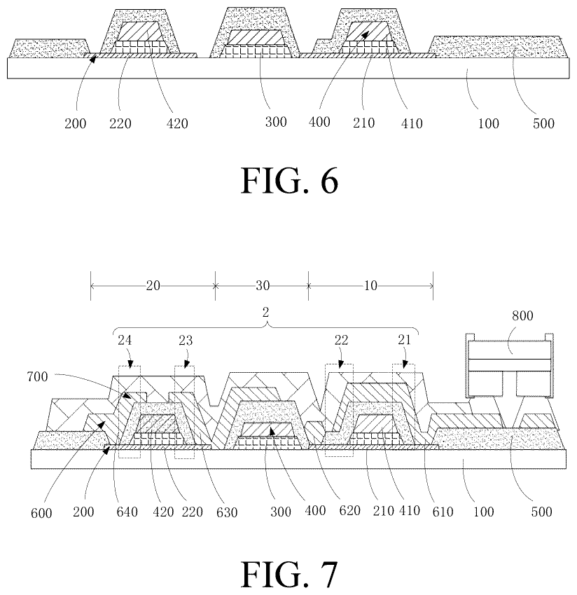

S30: As shown in FIG. 6, forming a second insulating layer 500 on the substrate 100, the active layer 200, the first insulating layer 300, and the first metal layer 400 to cover the first insulating layer 300 and the first metal layer 400.

S40: Forming a second metal layer 600 on the second insulating layer 500, where the second metal layer 600 includes a source-drain metal sub-layer formed in the TFT area.

S50: Forming a barrier layer 700 above the active layer 200, where the TFT area includes an active layer exposed area 2 located between the gate sub-layer and the source-drain metal sublayer, and an orthographic projection of the barrier layer 700 on the active layer 200 covers at least part of an orthographic projection of the active layer exposed area 2 on the active layer 200.

It is understandable that, as shown in FIG. 7, the material of the source-drain metal sub-layers may be the same as the material of the barrier layer 700. In addition, the source-drain metal sub-layers and the barrier layer 700 are manufactured by the same process, so that the source-drain metal sub-layers and the barrier layer 700 are integrally formed. It prevents the structure of the thin film transistor from affecting the performance of the device due to the penetration of water and oxygen or the direct irradiation of light. On the basis of improving the weather resistance of the thin film transistor device, it also prevents the increase of the production cost caused by the additional processes. In addition, it should be noted that in step S20: After forming the first insulating layer 300 and the first metal layer 400, it may further include a step of metalizing the connecting portions of the active layer 200 and the first source 610, the first drain 620, the second source 630, and the second drain 640.

As described above, in this application, a barrier layer 700 is provided at the active layer exposed area 2 between the gate sub-layer and the source-drain metal sub-layers, so that the orthographic projection of the barrier layer 700 on the active layer 200 covers at least part of the orthographic projection of the active layer exposed area 2 on the active layer 200. The barrier layer 700 not only plays a role in blocking water and oxygen, but also blocks direct irradiation of light to the active layer 200 at the active layer exposed area. This prevents the structure of the thin film transistor from being permeated by water and oxygen or directly irradiated by light to affect the performance of thin film transistor devices, thereby improving the weather resistance of the thin film transistor devices.

Some embodiments of the present application have been described in detail above. The embodiments are described for illustrative purposes only and are not intended to limit the present application. Many modifications or equivalent substitutions with respect to the embodiments may occur to those of ordinary skill in the art based on the present application and thus shall fall within the scope of the present application defined by the appended claims.

What is claimed is:

1. An array substrate, comprising:
a substrate;
an active layer disposed on the substrate;
a first insulating layer disposed on the substrate and the active layer;
a first metal layer disposed on the first insulating layer;
a second insulating layer disposed on the substrate, the active layer, the first insulating layer and the first metal layer and covering the first insulating layer and the first metal layer; and
a second metal layer disposed on the second insulating layer,
wherein the array substrate has a thin film transistor (TFT) area, the first metal layer comprises a gate sub-layer located in the TFT area, the second metal layer comprises a source-drain metal sub-layer located in the TFT area, the TFT area comprises an active layer exposed area located between the gate sub-layer and the source-drain metal sub-layer;
wherein the array substrate further comprises a barrier layer located above the active layer, and an orthographic projection of the barrier layer on the active layer covers at least part of an orthographic projection of the active layer exposed area on the active layer; and
wherein the TFT area comprises a driving TFT sub-area, the gate sub-layer comprises a first gate located in the driving TFT sub-area, the active layer comprises a first active sub-layer located in the driving TFT sub-area, the barrier layer comprises a first barrier sub-layer located in the driving TFT sub-area, and an orthographic projection of the first barrier sub-layer on the first active sub-layer covers at least part of an orthographic projection of the first gate on the first active sub-layer.

2. The array substrate according to claim 1, wherein the first barrier sub-layer comprise a barrier body disposed above the first gate, and an orthographic projection of the barrier body on the first active sub-layer completely covers the orthographic projection of the first gate on the first active sub-layer.

3. The array substrate according to claim 2, wherein the source-drain metal sub-layer comprises a first source located in the driving TFT sub-area, the active layer exposed area comprises a first exposed sub-area located between the first source and the first gate; and
wherein the first barrier sub-layer further comprises a first branch disposed at a side of the barrier body and spaced apart from the barrier body, the first branch extends from the side of the barrier body to the first exposed sub-area, and an orthographic projection of the first branch on the first active sub-layer covers at least part of an orthographic projection of the first exposed sub-area on the first active sub-layer.

4. The array substrate according to claim 3, wherein an end of the first branch away from the barrier body is connected to the first source.

5. The array substrate according to claim 2, wherein the source-drain metal sub-layer comprises a first source located in the driving TFT sub-area, the active layer exposed area comprises a first exposed sub-area located between the first source and the first gate; and
wherein the first barrier sub-layer further comprises a first branch extending from one end of the barrier body to the first exposed sub-area, and an orthographic projection of the first branch on the first active sub-layer covers at least part of an orthographic projection of the first exposed sub-area on the first active sub-layer.

6. The array substrate according to claim 5, wherein an end of the first branch away from the barrier body is connected to the first source.

7. The array substrate according to claim 5, wherein the source-drain metal sub-layer further comprises a first drain located in the driving TFT sub-area, the active layer exposed area further comprises a second exposed sub-area located between the first drain and the first gate; and
wherein the first barrier sub-layer further comprises a second branch disposed at a side of the barrier body away from the end of the barrier body and spaced apart from the barrier body, the second branch extends from the side of the barrier body to the second exposed sub-area, and an orthographic projection of the second branch on the first active sub-layer covers at least part of an orthographic projection of the second exposed sub-area on the first active sub-layer.

8. The array substrate according to claim 7, wherein an end of the first branch away from the barrier body is connected to the first source, and/or an end of the second branch away from the barrier body is connected to the first drain.

9. The array substrate according to claim 2, wherein the source-drain metal sub-layer comprises a first drain located in the driving TFT sub-area, the active layer exposed area comprises a second exposed sub-area located between the first drain and the first gate; and
wherein the first barrier sub-layer further comprises a second branch disposed at a side of the barrier body and spaced apart from the barrier body, the second branch extends from the side of the barrier body to the second exposed sub-area, and an orthographic projection of the second branch on the first active sub-layer covers at least part of an orthographic projection of the second exposed sub-area on the first active sub-layer.

10. The array substrate according to claim 9, wherein an end of the second branch away from the barrier body is connected to the first drain.

11. The array substrate according to claim 2, wherein the source-drain metal sub-layer comprises a first drain located in the driving TFT sub-area, the active layer exposed area comprises a second exposed sub-area located between the first drain and the first gate; and
wherein the first barrier sub-layer further comprises a second branch extending from one end of the barrier body to the second exposed sub-area, and an orthographic projection of the second branch on the first active sub-layer covers at least part of an orthographic projection of the second exposed sub-area on the first active sub-layer.

12. The array substrate according to claim 11, wherein an end of the second branch away from the barrier body is connected to the first drain.

13. The array substrate according to claim 11, wherein the source-drain metal sub-layer further comprises a first source located in the driving TFT sub-area, the active layer exposed area further comprises a first exposed sub-area located between the first source and the first gate; and
wherein the first barrier sub-layer further comprises a first branch disposed at a side of the barrier body away from the end of the barrier body and spaced apart from the barrier body, the first branch extends from the side of the barrier body to the first exposed sub-area, and an orthographic projection of the first branch on the first active sub-layer covers at least part of an orthographic projection of the first exposed sub-area on the first active sub-layer.

14. The array substrate according to claim 13, wherein an end of the first branch away from the barrier body is connected to the first source, and/or an end of the first branch away from the barrier body is connected to the first drain.

15. The array substrate according to claim 2, further comprising a storage capacitor area, wherein the first metal layer further comprises a first electrode plate of a storage capacitor located in the storage capacitor area, the second metal layer comprises a second electrode plate of the storage capacitor located in the storage capacitor area, an orthographic projection of the second electrode plate on the substrate covers at least part of an orthographic projection of the first electrode plate on the substrate, and a size of a facing area of the first electrode plate and the second electrode plate is adjusted according a size of the storage capacitor.

16. The array substrate according to claim 1, wherein the first barrier sub-layer comprises a barrier body, a first branch and a second branch which are disposed at intervals.

17. The array substrate according to claim 16, wherein the source-drain metal sub-layer comprises a first source and first drain located in the driving TFT sub-area, the active layer exposed area comprises a first exposed sub-area located between the first source and the first gate and a second exposed sub-area located between the first drain and the first gate; and
wherein the barrier body disposed above the first gate, the first branch and the second branch extend respectively from opposite sides of the barrier body to the first exposed sub-area and the second exposed sub-area, an orthographic projection of the first branch on the first active sub-layer covers at least part of an orthographic projection of the first exposed sub-area on the first active sub-layer, and/or an orthographic projection of the second branch on the first active sub-layer covers at least part of an orthographic projection of the second exposed sub-area on the first active sub-layer.

18. The array substrate according to claim 17, wherein an end of the first branch away from the barrier body is connected to the first source, and/or an end of the second branch away from the barrier body is connected to the first drain.

19. The array substrate according to claim 16, further comprising a storage capacitor area, wherein the first metal layer further comprises a first electrode plate of a storage capacitor located in the storage capacitor area, the second metal layer comprises a second electrode plate of the storage capacitor located in the storage capacitor area, an orthographic projection of the second electrode plate on the substrate covers at least part of an orthographic projection of the first electrode plate on the substrate, and a size of a facing area of the first electrode plate and the second electrode plate is adjusted according a size of the storage capacitor.
